(19) United States
(12) Patent Application Publication
(10) Pub. No.: US 2025/0147414 A1
(43) Pub. Date: May 8, 2025

(54) CROSS-LINKERS FOR METALLIC PHOTORESIST

(71) Applicant: Taiwan Semiconductor Manufacturing Company LTD, Hsinchu (TW)

(72) Inventors: Shi-Cheng Wang, Tainan (TW); An-Ren Zi, Hsinchu (TW); Ching-Yu Chang, Yuansun (TW)

(21) Appl. No.: 18/386,658

(22) Filed: Nov. 3, 2023

(51) Int. Cl. G03F 7/004; G03F 7/16

(52) U.S. Cl. CPC G03F 7/0042; G03F 7/168

(57) ABSTRACT

Methods and materials for improving the hardness of a metallic photoresist used in EUV photolithography are disclosed. A metallic cross-linker is used with the metallic photoresist. The cross-linker comprises a metal core and a plurality of ligands. The ligands may comprise at least one vinyl group or at least one acetylene group; or comprise an acrylate; or comprise a cinnamate; or be unable to participate in a crosslinking reaction. Upon radiation exposure, the ligands separate from the metal core, and the metal core can crosslink, or the ligands may crosslink. The resulting photoresist layer has increased hardness and higher EUV light sensitivity, which permits a reduced radiation dosage.

### BACKGROUND

Integrated circuits are formed on a semiconductor wafer. Photolithographic patterning processes use ultraviolet light to transfer a mask pattern to a photoresist on a semiconductor wafer. Etching processes may then be used to transfer to the pattern to a layer below the photoresist. This process is repeated multiple times with different patterns to build different layers on the wafer substrate and make a useful device.

High-resolution lithography processes help to obtain smaller feature sizes. An example of one such process is extreme ultraviolet (EUV) lithography, which uses wavelengths of about 10 nanometers (nm) to about 100 nm.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a flow chart illustrating a method for preparing a patterned photoresist layer and etching a layer of a semiconducting device, in accordance with some embodiments.

FIG. 1B is a second flow chart illustrating other aspects of the method.

FIG. 2A is a cross-sectional view of a substrate prior to starting the method of FIG. 1A and FIG. 1B.

FIG. 2B is a cross-sectional view of a substrate with a first material layer located upon the substrate, again prior to starting the method of FIG. 1A and FIG. 1B.

FIG. 3 is a cross-sectional view of the substrate with two underlayers applied upon the first material layer.

FIG. 4 is a cross-sectional view of the substrate with a photoresist layer applied upon the two underlayers.

FIG. 5 is a cross-sectional view of the substrate after radiation exposure, with the photoresist layer now including soluble regions and insoluble regions.

FIG. 6 is a cross-sectional view of the substrate after development, with a patterned photoresist layer.

FIG. 7 is a cross-sectional view of the final structure with a patterned first material layer.

FIG. 8 is an illustration of an extreme ultraviolet (EUV) photolithography system for exposing the photoresist layer to EUV radiation, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The term “hydrocarbon” is used herein to refer to a radical composed from a chain of carbon atoms which can be fully saturated or unsaturated, and is not aromatic. The hydrocarbon radical may be linear, branched, or cyclic. The hydrogen atoms may be substituted with other radicals.

The term “alkyl” is used herein to refer to a radical composed from a chain of carbon atoms which is fully saturated (i.e. contains only single bonds). The alkyl radical may be linear, branched, or cyclic.

The terms “aromatic” or “aryl” refer to a group that has a ring system containing a delocalized conjugated pi system with a number of pi-electrons that obeys Huckel's Rule. The ring system is composed of carbon atoms and hydrogen atoms. Examples of aromatic groups include phenyl (derived from benzene) and other polycyclic aromatic hydrogens such as naphthyl (derived from naphthalene) or phenanthryl (derived from phenanthrene). Generally, the aromatic group is planar and un-charged.

The term “alkenyl” as used herein refers to a radical composed from a chain of carbon atoms which contains at least one carbon-carbon double bond and is not aromatic. The alkenyl radical may be linear, branched, or cyclic.

The term “alkynyl” as used herein refers to a radical composed from a chain of carbon atoms which contains at least one carbon-carbon triple bond and is not aromatic. The alkynyl radical may be linear, branched, or cyclic.

The terms “vinyl” or “ethenyl” as used herein refer specifically to a functional group of the formula —(C═C)—, having a carbon-carbon double bond, with each carbon atom being bonded to two other atoms, and which is not aromatic. The vinyl group is generally present in a hydrocarbon group (linear, branched, or cyclic). A vinyl group is able to participate in cross-linking reactions, and so the carbon-carbon double bonds present in an aromatic group are not considered to be vinyl groups.

The terms “acetylene” or “ethynyl” as used herein refer specifically to a functional group of the formula —(C≡C)—, having a carbon-carbon triple bond, with each carbon atom being bonded to one other atom, and which is not aromatic. The acetylene group is generally present in a hydrocarbon group (linear, branched, or cyclic).

The term “halogen” as used herein refers to fluorine, chlorine, bromine, and iodine.

The term “substituted” refers to at least one hydrogen atom on the named radical being substituted with another functional group that contains a heteroatom (in other words, at least one atom of the functional group is not carbon or hydrogen). An example of a substituted alkyl group is a perhaloalkyl group, wherein one or more hydrogen atoms in an alkyl group are replaced with halogen atoms.

The present disclosure may refer to temperatures for certain process steps. It is noted that these generally refer to the temperature at which the heat source (e.g. furnace) is set, and do not necessarily refer to the temperature which must be attained by the material being exposed to the heat.

The term “ambient temperature” or “room temperature” refers to a temperature of 20° C. to 25° C.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

The present disclosure relates to various methods for improving the operation of a metallic photoresist. In this regard, chemically amplified photoresist may be considered as operating through a multi-step reaction mechanism. First, when exposed to EUV radiation, the photoresist absorbs photons from the radiation. Second, secondary electrons are emitted by the photoresist, and thermal electrons are also generated. Third, photo-acid generators (PAGs) react with these electrons to generate photoacids. Fourth, the photoacids diffuse through the photoresist matrix. Fifth and last, the photoacid catalyzes the degradation of acid-sensitive groups from the photoresist, also known as deprotection. The photoacid is not consumed in this reaction, and can thus catalyze multiple deprotection reactions. The deprotected photoresist differs from the original photoresist in solubility. This difference in the photoresist between exposed areas and non-exposed areas permits patterning of the photoresist, which is used to build different layers on the wafer substrate. A metallic photoresist includes metal atoms to increase photon absorption, i.e. the first step of the reaction mechanism. The patterned photoresist layer is then used as a mask for performing various processes, such as etching a lower layer or depositing a new layer.

The present disclosure relates to methods and materials for increasing the hardness of the resulting metallic photoresist layer and/or for reducing the radiation dosage needed to pattern the metallic photoresist. The metallic photoresist is exposed to a metallic cross-linker having a structure as described herein during the photoresist development process. The photoresist development process includes the steps of coating the substrate, a prebake or softbake, radiation exposure, an optional post-exposure bake, development, and an optional hardbake. The metallic cross-linker can be applied during or between any of the process steps prior to radiation exposure. An increased hardness provides higher etch selectivity, better critical dimension (CD) control, and increases the aspect ratio that can be achieved. Initially, the metallic photoresist and the metallic cross-linker will be described. Next, other components that may be present in photoresist solutions and methods for using the photoresist solutions will be described.

### Metallic Photoresist

The metallic photoresist of the present disclosure comprises a metal core and one or more ligands attached to or connected to the metal core. The ligand(s) may be attached via covalent, ionic, or metallic bonds or via van der Waals forces to the metal core.

The metal core of the metallic photoresist includes a metallic element. The metallic element may be present as a pure metal (i.e. atom), an ion, a compound (for example a metal oxide, metal nitride, metal oxynitride, metal silicide, metal carbide, etc.), or as an alloy of multiple metal atoms. Desirably, the metallic element has a high EUV photoabsorption. Examples of suitable metallic elements include silver (Ag), cadmium (Cd), indium (In), tin (Sn), antimony (Sb), tellurium (Te), cesium (Cs), gold (Au), mercury (Hg), titanium (Ti), lead (Pb), bismuth (Bi), polonium (Po), astatine (At), barium (Ba), lanthanum (La), cerium (Ce), hafnium (Hf), zirconium (Zr), chromium (Cr), tungsten (W), molybdenum (Mo), iron (Fe), ruthenium (Ru), osmium (Os), cobalt (Co), rhodium (Rh), iridium (Ir), nickel (Ni), palladium (Pd), platinum (Pt), copper (Cu), zinc (Zn), aluminum (Al), gallium (Ga), thallium (Tl), and germanium (Ge). In more specific embodiments, the metal core of the metallic photoresist comprises Ag, Cd, In, Sn, Sb, Te, Cs, Au, Hg, Ti, Pb, Bi, Po, At, Ba, La, or Ce. The metallic elements in the metal core of the metallic photoresist may comprise from about 0.01 wt % to about 7 wt % of the photoresist solution. In some particular embodiments, only one metallic element is present in the metal core. In other embodiments, multiple metallic elements are present in the metal core.

The ligand(s) are attached to the metal core, and this attachment determines whether the photoresist is soluble or insoluble when exposed to developer. One function of the ligand(s) is to protect the metal core from condensation prior to radiation exposure. In particular embodiments, there are from 1 to about 18 ligands attached to the metal core. In some embodiments, the ligands are hydrolysable. When hydrolyzed, the metal core can undergo condensation reactions to form an organometallic polymer for the photoresist. In other embodiments, the ligands may be cleaved from the metal core during radiation exposure or heat treatment to permit the metal cores to crosslink with each other and form the metallic photoresist.

The individual ligands themselves can be synthesized using conventional methods known in the art. The metal core can also be synthesized using conventional methods known in the art. The ligand(s) can be attached to the metal core using conventional methods known in the art. The metallic photoresist is suited for EUV photolithography processes where a pitch of less than 40 nanometers (nm) is desired.

### Metallic Cross-Linker

The metallic cross-linkers of the present disclosure comprise a metal core and a plurality of ligands. The ligands are usually attached to the metal core via covalent bonds, but attachment through ionic or metallic bonds or via van der Waals forces is also contemplated. The molecular weight of the cross-linker may be from about 30 daltons to about 2000 daltons (also known as atomic mass unit or amu). The metallic cross-linker has the general structure of Formula (I):

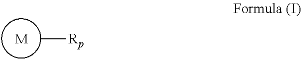

where M represents the metal core; R represents the ligand, and 2≤p≤12.

The metal core of the metallic cross-linker includes a metallic element. The metallic element may be present as a pure metal (i.e. atom), an ion, a compound (for example a metal oxide, metal nitride, metal oxynitride, metal silicide, metal carbide, etc.), or as an alloy of multiple metal atoms. Desirably, the metallic element has a high EUV photoabsorption. Examples of suitable metallic elements include silver (Ag), cadmium (Cd), indium (In), tin (Sn), antimony (Sb), tellurium (Te), cesium (Cs), gold (Au), mercury (Hg), titanium (Ti), lead (Pb), bismuth (Bi), polonium (Po), astatine (At), barium (Ba), lanthanum (La), cerium (Ce), hafnium (Hf), zirconium (Zr), chromium (Cr), tungsten (W), molybdenum (Mo), iron (Fe), ruthenium (Ru), osmium (Os), cobalt (Co), rhodium (Rh), iridium (Ir), nickel (Ni), palladium (Pd), platinum (Pt), copper (Cu), zinc (Zn), aluminum (Al), gallium (Ga), thallium (Tl), and germanium (Ge). In more specific embodiments, the metal core of the cross-linker comprises Ag, Cd, In, Sn, Sb, Te, Cs, Au, Hg, Ti, Pb, Bi, Po, or At. The metallic elements in the metal core of the metallic cross-linker may comprise from about 0.001 wt % to about 5 wt % of the photoresist solution. In some particular embodiments, only one metallic element is present in the metal core. In other embodiments, multiple metallic elements are present in the metal core. The metal core may be a metal cluster composed of 1 to 12 metal atoms.

In particular embodiments, the metal core of the cross-linker further comprises oxygen, such that the metal core may be described as being formed from a metal oxide. In other embodiments, the metal core further comprises saturated carbon linkages between metal atoms. The metal core may be linear, branched, or cyclic, and in some cases may be three-dimensional.

The ligand(s) of the metallic cross-linker are attached to the metal core. One function of the ligand(s) is to protect the metal core from condensation prior to radiation exposure. The ligands are photosensitive, and are cleaved from the metal core during radiation exposure. In particular embodiments, there are from 2 to 12 ligands attached to the metal core. In particular embodiments, each ligand contains from 1 to 20 carbon atoms, although other ranges and values are within the scope of this disclosure.

Four different types of ligands are contemplated for use with the metallic cross-linker of the present disclosure, as described herein. The first type of ligand, also referred to as a Type 1 ligand herein, after being cleaved from the metal core, can react to form crosslinks between the ligands themselves. The second type of ligand, also referred to as a Type 2 ligand herein, can also react to form crosslinks when the ligands are cleaved from the metal core. However, the Type 2 ligands have a different structure from the Type 1 ligands. The third type of ligand, also referred to as a Type 3 ligand herein, can form dimer structures. The fourth type of ligand, also referred to as a Type 4 ligand herein, permits crosslinking between metal cores to occur when the ligands are cleaved from the metal core.

It is contemplated that in some embodiments, all of the ligands on the metal core of the metallic cross-linker are of the same type. In other words, the ligands of the metallic cross-linker are all Type 1 ligands, all Type 2 ligands, all Type 3 ligands, or all Type 4 ligands.

In other embodiments, the metallic cross-linker contains ligands of only two different types. For example, the ligands of the metallic cross-linker may be only Type 1 and Type 2 ligands; or only Type 1 and Type 3 ligands; or only Type 1 and Type 4 ligands; or only Type 2 and Type 3 ligands; or only Type 2 and Type 4 ligands; or only Type 3 and Type 4 ligands. In some particular embodiments, the mole ratio between the two ligand types may be from about 10:1 to about 1:10, including from about 5:1 to about 1:5 or from about 2:1 to about 1:2. However, other values and ranges are also within the scope of this disclosure.

In other embodiments, the metallic cross-linker contains ligands of only three different types. For example, the ligands of the metallic cross-linker may be only Type 1, Type 2, and Type 3 ligands; or only Type 1, Type 2, and Type 4 ligands; or only Type 1, Type 3, and Type 4 ligands; or only Type 2, Type 3, and Type 4 ligands. In some particular embodiments, the mole ratio between any two ligand types may be from about 10:1 to about 1:10, including from about 5:1 to about 1:5 or from about 2:1 to about 1:2. However, other values and ranges are also within the scope of this disclosure. In some more specific embodiments, the three ligand types are present in about equal amounts.

In still other embodiments, the metallic cross-linker contains ligands of all four different types. In some particular embodiments, the mole ratio between any two ligand types may be from about 10:1 to about 1:10, including from about 5:1 to about 1:5 or from about 2:1 to about 1:2. However, other values and ranges are also within the scope of this disclosure. In some more specific embodiments, the four ligand types are present in about equal amounts.

The first type of ligand (i.e. Type 1 ligand) is unsaturated, and can crosslink when cleaved. For example, the Type 1 ligand may contain one or more vinyl groups or acetylene groups. In particular embodiments, each Type 1 ligand may contain from 2 to 20 carbon atoms (including all substituents). The metal atom can be attached to any carbon atom within the ligand.

In some embodiments, the Type 1 ligand is an alkene. In more specific embodiments, the Type 1 ligand is a linear or branched alkene. Some non-limiting examples of Type 1 alkene ligands are shown below. For ease of reference, the metal core is illustrated as an M surrounded by a circle, and only one ligand is illustrated as being attached to the metal core via a covalent bond.

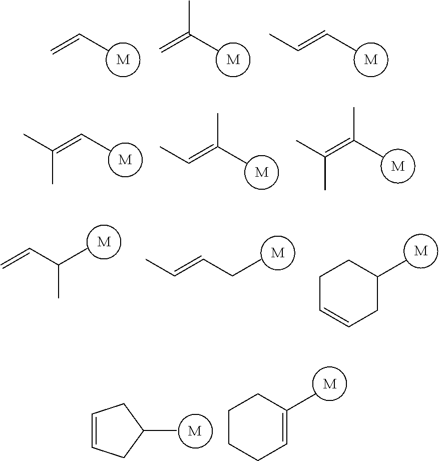

In some other specific embodiments, the Type 1 ligand is an alkyne. In more specific embodiments, the Type 1 ligand is a linear or branched alkyne. Some non-limiting examples of Type 1 alkyne ligands are shown below.

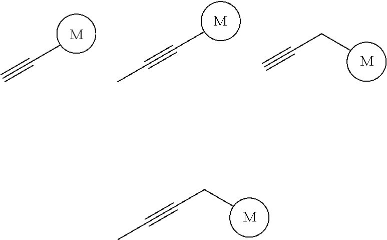

In some other specific embodiments, the Type 1 ligand contains at least one aromatic group and one or more vinyl groups or acetylene groups. The aromatic group may be, for example, benzene, naphthalene, or anthracene. Multiple aromatic groups may include, for example, bi-phenyl or tri-phenyl. It is noted the vinyl group may be present as part of a longer sidechain, for example of the general formula —CₙH₂ₙ—(CH═CH₂). Additional substituents may also be present. Some non-limiting examples of these Type 1 ligands are shown below.

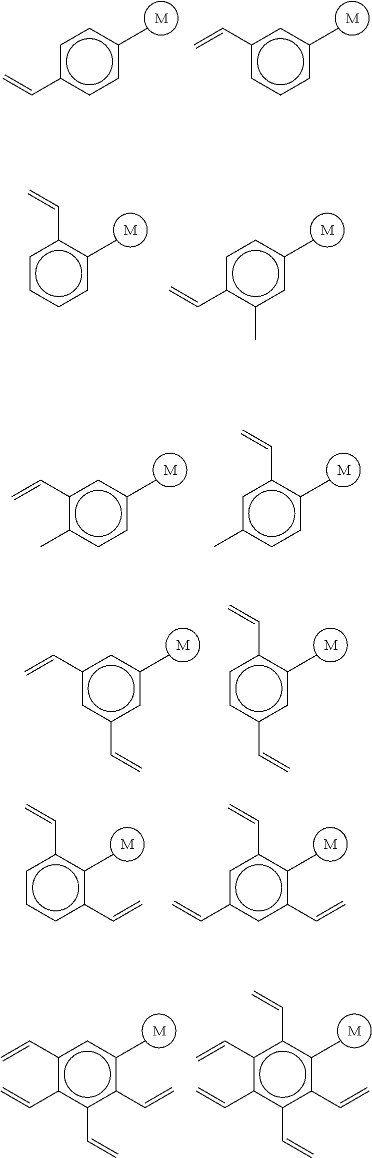

More broadly, some Type 1 ligands containing at least one aromatic group and one or more vinyl groups or acetylene groups may fall within the general structure of Formula (1):

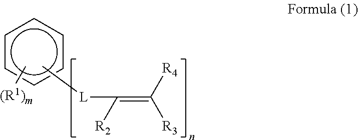

where R₁, R₂, R₃, and R₄, are independently hydrogen or hydrocarbon; L is alkyl or is a single bond; n is an integer from 1 to 5; and m +n is an integer from 1 to 5. Such Type 1 ligands may also be referred to as styryl ligands

The second type of ligand (i.e. Type 2 ligand) is an acrylate or methacrylate. Again, the Type 2 ligand can crosslink when cleaved. The acrylate has the general structure of Formula (2):

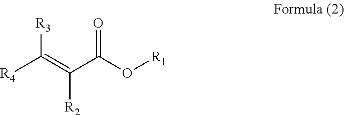

where R₁, R₂, R₃, and R₄ are independently hydrogen, hydrocarbon, or substituted hydrocarbon. In more particular embodiments, the substituents R₁, R₂, R₃, and R₄ are independently hydrogen or alkyl. For a methacrylate, R₂ is methyl.

In particular embodiments, each Type 2 ligand may contain from 3 to 12 carbon atoms (including all substituents). Some non-limiting examples of Type 2 ligands are shown below.

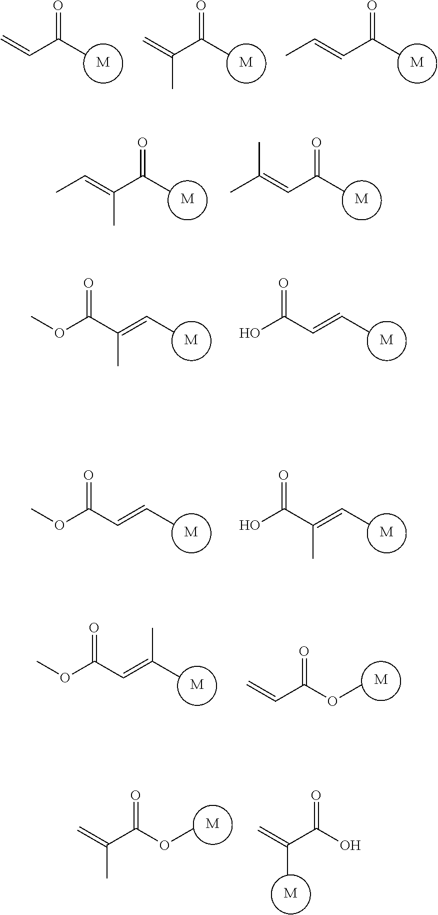

As seen here, the metal atom can be attached to any carbon atom within the ligand, or to the oxygen atom of the carboxylic acid portion of the acrylate. It is noted that in some embodiments, the metal core may also replace the-OH moiety of the carboxylic acid portion of the acrylate.

The third type of ligand (i.e. Type 3 ligand) is a cinnamate. The Type 3 ligand will form dimer structures crosslink when cleaved. The cinnamate has the general structure of Formula (3):

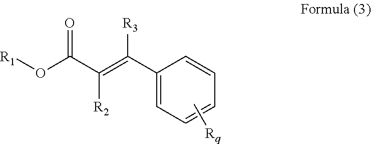

where R, R₁, R₂, and R₃ are independently hydrogen, hydrocarbon, or substituted hydrocarbon; and q is an integer from 0 to 5.

In particular embodiments, each Type 3 ligand may contain from 9 to 20 carbon atoms (including all substituents). Some non-limiting examples of Type 3 ligands are shown below.

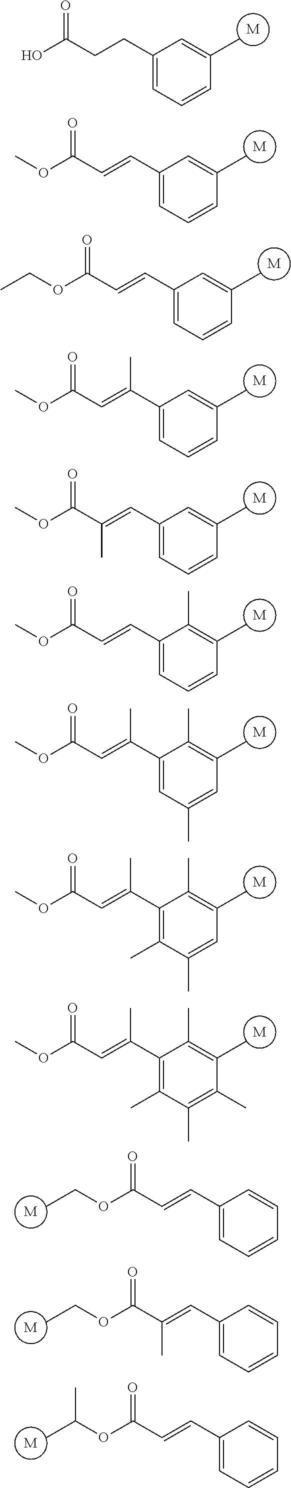

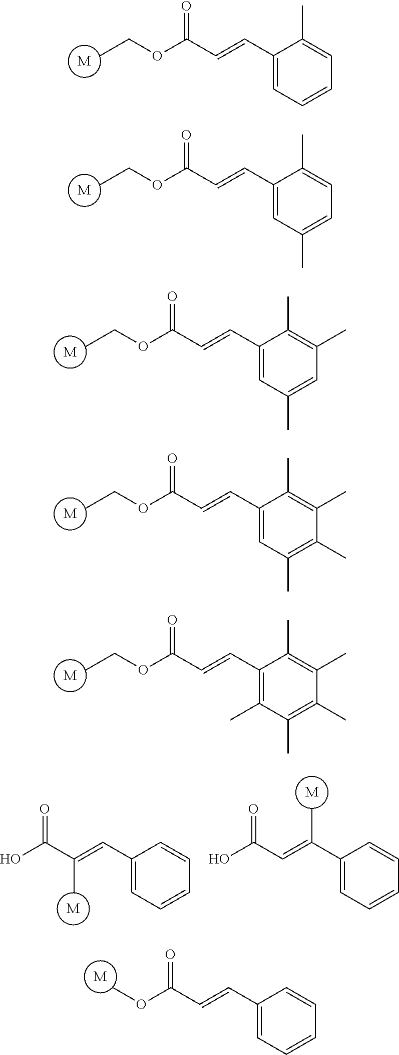

As seen here, the metal atom can be attached to any carbon atom within the cinnamate ligand, or to the oxygen atom of the carboxylic acid portion of the cinnamate. It is noted that in some embodiments, the metal core may also replace the —OH moiety of the carboxylic acid portion of the cinnamate.

When the fourth type of ligand (i.e. Type 4 ligand) is cleaved from the metal core, the metal core can form crosslinks with other metal cores. The Type 4 ligand cannot and does not participate in any crosslinking reactions. It is contemplated that the Type 4 ligand may remain in the photoresist, or may evaporate, or may be dissolved in cleaning solvent, or otherwise be removed from the photoresist during the photoresist baking and development process. In particular embodiments, each Type 4 ligand may contain from 1 to 20 carbon atoms (including all substituents). The metal atom can be attached to any carbon atom within the ligand.

In some embodiments, the Type 4 ligand is an alkane. In more specific embodiments, the Type 4 ligand is a linear or branched alkane. In other embodiments, the Type 4 ligand is a primary alkane, where the carbon atom carrying the electronic charge is connected to only one other carbon atom. Some non-limiting examples of Type 4 alkane ligands are shown below.

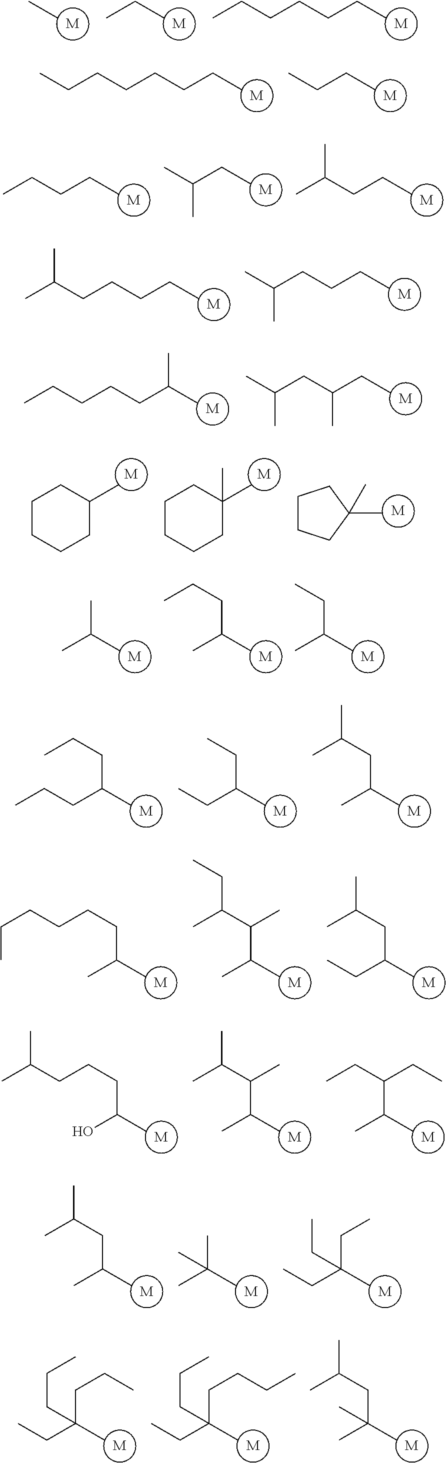

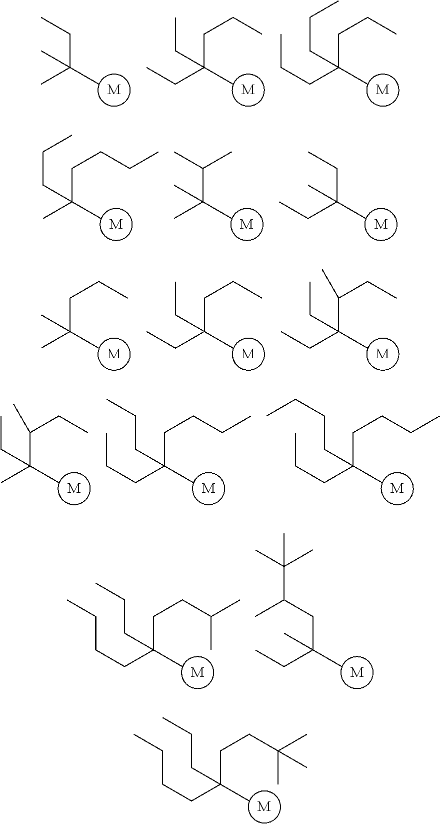

Referring to all four ligand types, any carbon atom may also be replaced with a heteroatom, such as oxygen, nitrogen, sulfur, or phosphorus. Any hydrogen atom may be substituted with a substituent such as, for example, halogen, —OH, —SH, —NO₂, —SO₂R, —SO₃R, —CN, —COR, —CO₂R, or —CONR₂, where each R is independently hydrogen or alkyl.

In some embodiments, the Type 1, Type 2, Type 3, or Type 4 ligands previously described have 1, 2, or 3 carbon atoms which have been replaced with oxygen or nitrogen. In other embodiments, the Type 1, Type 2, Type 3, or Type 4 ligands previously described have one or a plurality of hydrogen atoms which are substituted with fluorine.

The individual ligands themselves can be synthesized using conventional methods known in the art. The metal core can also be synthesized using conventional methods known in the art. The ligand(s) can be attached to the metal core using conventional methods known in the art to obtain the metallic cross-linker.

The metallic cross-linker is used in an amount of about 0.001 at % to about 50 at % relative to the metallic photoresist. The metallic element(s) in the metal core of the metallic cross-linker may be the same as or different from the metallic element(s) in the metal core of the metallic photoresist.

As will be described in further detail herein, the photoresist development process includes the steps of coating the substrate, a prebake or softbake, radiation exposure, an optional post-exposure bake, development, and an optional hardbake. The metallic cross-linker can be used during any of the process steps prior to radiation exposure, or could be used between any of those process steps. The metallic cross-linker may be provided in a liquid phase or a gas/vapor phase or as a solid, depending on the operating temperature and pressure of the particular process step.

### Photoresist Solution or Treatment Solution

A photoresist solution is generally used to prepare a photoresist layer on a semiconducting wafer substrate. The photoresist solution includes a metallic photoresist as described above. The photoresist solution may also include the metallic cross-linker as described, or another cross-linker. The photoresist solution also includes a solvent in which the photoresist and cross-linker are carried. The solvent may be, for example, water, propylene glycol methyl ether acetate (PGMEA), propylene glycol monomethyl ether (PGME), 1-ethoxy-2-propanol (PGEE), gamma-butyrolactone (GBL), cyclohexanone (CHN), ethyl lactate (EL), methanol, ethanol, propanol, n-butanol, acetone, dimethylformamide (DMF), isopropyl alcohol (IPA), tetrahydrofuran (THF), methyl isobutyl carbinol (MIBC), n-butyl acetate (nBA), 2-heptanone (MAK), or isobutyl propionate, or other suitable solvent.

The metallic photoresist may comprise from about 0.1 wt % to about 50 wt % of the photoresist solution. The metallic cross-linker may comprise from about 0.1 wt % to about 20 wt % of the photoresist solution. The remainder of the photoresist solution is the solvent.

In some embodiments, the metallic elements in the metal core of the metallic photoresist may comprise from about 0.01 wt % to about 7 wt % of the photoresist solution. The metallic elements in the metal core of the metallic cross-linker may comprise from about 0.001 wt % to about 5 wt % of the photoresist solution. Alternatively, the metallic cross-linker is used in an amount of about 0.1 wt % to about 30 wt % relative to the metallic photoresist.

The photoresist solution may also include a photoacid generator (PAG). Upon exposure to radiation, the photoacid generator decomposes to generate an acid. The photoresist solution may also include a thermal acid generator (TAG). At high temperatures, the thermal acid generator decomposes to generate an acid. The acids catalyze chemical reactions which change the solubility of the photoresist, for example by cleaving the ligands from the metal core. Quenchers may also be present to enhance pattern solution by neutralizing acid which may diffuse into non-exposed areas of the photoresist.

When the metallic cross-linker is not included in the photoresist solution, it is typically provided in a liquid form as a treatment solution. The solvent of the treatment solution may be any of the same solvents as used in the photoresist solution. The metallic cross-linker may be dissolved to saturation in the solvent to form the treatment solution. In some embodiments, the metallic cross-linker may be dissolved to a final concentration of about 10 ppm to about 200,000 ppm (i.e. about 0.001 wt % to about 20 wt %). Other values and ranges are also within the scope of this disclosure.

### Process

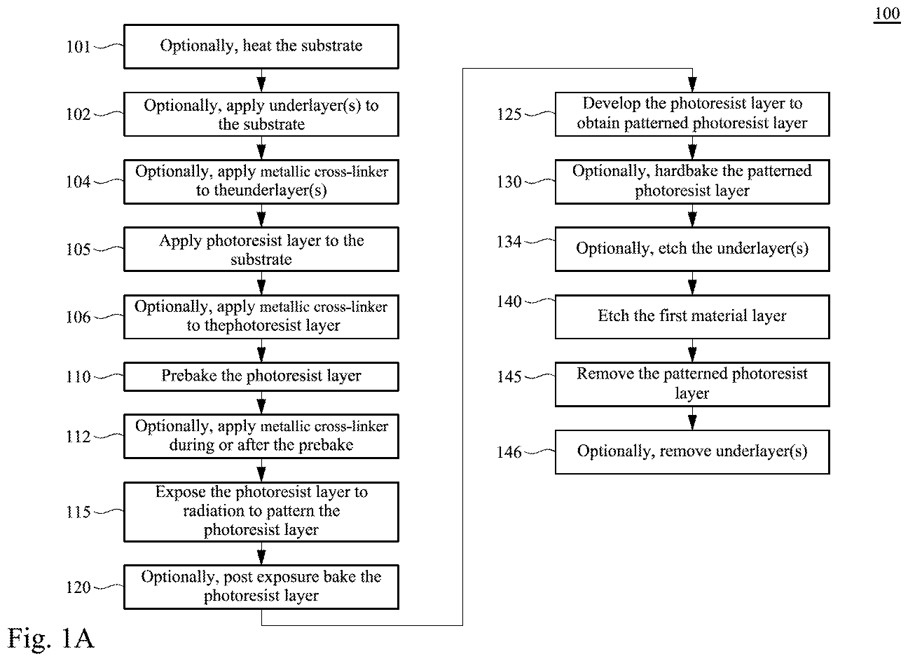

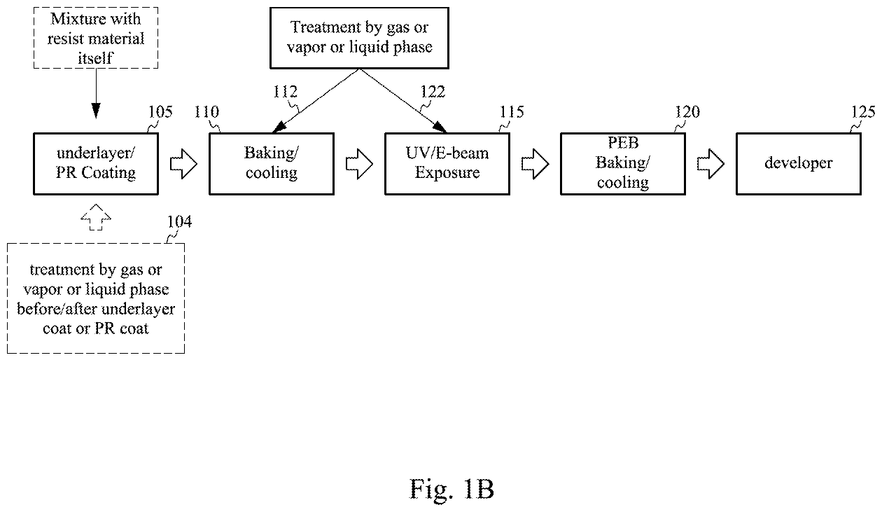

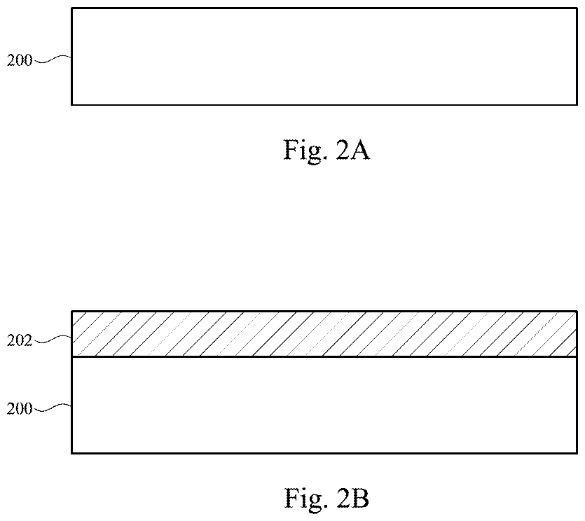

FIG. 1A is a flow chart illustrating a method 100 for preparing a patterned photoresist layer and etching a layer of a semiconducting device, in accordance with some embodiments. FIG. 1B is another flow chart illustrating other aspects of the method. In the discussion below, FIG. 1A will generally be referred to. Some steps of the method are also illustrated in FIGS. 2A-7. These figures provide different views for better understanding.

Referring first to FIG. 2A, this figure shows one example of the beginning state of the substrate 200 prior to any processing steps. The substrate is usually a wafer made of a semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon. As illustrated here, no additional layers are present upon the substrate 200.

In contrast, in FIG. 2A, a first material layer 202 is present upon the substrate 200. The first material layer may be any material that may be used in a semiconducting device or integrated circuit. For example, the first material layer could be made of an insulating material, such as silicon dioxide (SiO2) or silicon nitride (SiN), silicon oxynitride (SiON), fluoride-doped silicate glass, or other dielectric material. As another example, the first material layer could be made of an electrically conductive material, such as polysilicon or a metal like aluminum, copper, titanium, or tungsten. The discussion below proceeds with a first material layer being present, for illustrative purposes only and with it being understood that the substrate can also be etched.

It may be desirable to heat the substrate prior to beginning the photoresist patterning process. This optional heating step 101 may improve resist adhesion by desorbing water present on the substrate surface and to thermally crack any hydroxide bonds present on an oxidized surface. The substrate can be heated to temperatures above 100° C. up to, for example, 200° C. for a period of several minutes. The substrate is then cooled back down to room temperature.

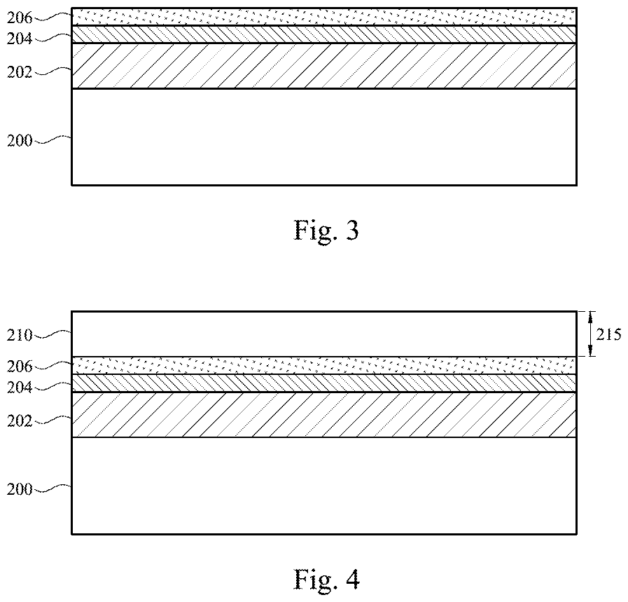

Referring again to FIG. 1A, in optional step 102, one or more underlayers are applied to the substrate. In this regard, the term “underlayer” is relative to the photoresist layer, and refers to any layers which may be applied to the layer that is desired to be etched prior to applying the photoresist layer. Put another way, any layers between the layer to be etched and the photoresist layer can be considered an underlayer. In one non-limiting example illustrated in FIG. 3, two underlayers 204, 206 are applied upon the first material layer 202.

As one example, the lower underlayer 204 may be a bottom anti-reflective coating (BARC). When a photoresist layer is applied to a reflective substrate, light reflection from the substrate/resist interface can create variations in light exposure, that cause problems with critical dimension (CD) control. For example, light can reflect into areas where exposure was not intended, changing the desired pattern. A BARC can be applied between the substrate and the photoresist layer to minimize or eliminate such problems. Examples of suitable BARCs include amorphous carbon and various organic polymers. The BARC layer is typically formed by spin coating, though other methods can also be used. The BARC coating or film is then baked or cured to induce crosslinking and solvent removal, and hardening of the BARC. In some particular embodiments, the baking occurs at a temperature of about 125° C. to about 275° C. In particular embodiments, the baking takes place for a time of about 30 seconds to about 250 seconds. The baking can be performed using a hot plate or similar equipment.

As another example, the upper underlayer 206 may be a hard mask layer. The hard mask layer may be formed from a dielectric material, a metal, or other suitable material. Examples of suitable dielectric materials may include silicon carbide, silicon nitride, silicon oxycarbide, or silicon oxynitride. The hard mask layer may be formed by any suitable process such as chemical vapor deposition (CVD), low-pressure CVD (LPCVD), plasma-enhanced CVD (PECVD), physical vapor deposition (PVD), atomic layer deposition (ALD), or spin coating. The BARC layer and the hard mask layer are also typically selected to have significantly different etching sensitivity towards the same etchant. Combined with the photoresist layer, this multi-layer resist pattern can also help improve line width roughness (LWR).

When underlayers are used, as indicated in optional step 104 of FIG. 1A, the metallic cross-linker can be mixed in with the materials for the underlayer or applied to either underlayer. This can be done by applying the metallic cross-linker in the liquid phase (e.g. a solution) or in the gas phase, for example during the baking/curing of the underlayer. Alternatively, the metallic cross-linker could be applied as a solid.

Next, in step 105 of FIG. 1A and as illustrated in FIG. 4, a photoresist (PR) layer 210 is applied over the substrate. The photoresist layer is formed by applying the photoresist solution containing the metallic photoresist and/or the metallic cross-linker. The photoresist solution may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist solution is then applied to the center of the substrate. The speed of the rotating platen is then increased to spread the resist evenly from the center of the substrate to the perimeter of the substrate. The rotating speed of the platen is then fixed, which can control the thickness of the final photoresist layer. FIG. 4 shows the resulting structure after this step.

Alternatively, as indicated in optional step 106 of FIG. 1A, the metallic cross-linker can be applied after the photoresist layer has been applied. Again, the metallic cross-linker could be applied in the liquid phase, for example by spin coating or spraying or misting the treatment solution upon the photoresist layer. Alternatively, the metallic cross-linker could be applied as a solid or a gas.

Next, in step 110 of FIG. 1A, the photoresist solution is prebaked to remove the solvent and harden the photoresist layer. This may also be referred to as a softbake. In some particular embodiments, the prebake occurs at a temperature of about 40° C. to about 100° C., including from about 250° C. to about 800° C. or from about 90° C. to about 110° C. The time for the prebake may depend upon the thickness of the photoresist layer 210, with longer times for greater thicknesses, and in particular embodiments from about 10 seconds to about 10 minutes. Referring to FIG. 4, the photoresist layer 210 may have a thickness 215 of about 10 nanometers to about 100 nanometers. The baking can be performed using a hot plate or oven, or similar equipment. As a result, the photoresist layer is formed on the substrate. The substrate and the other layers thereon are then cooled down to room temperature.

As indicated in optional step 112 of FIG. 1A, the metallic cross-linker can be applied during or after the prebake. The metallic cross-linker could be applied as a liquid, or can be vaporized by the heating that occurs in the prebake step and be applied as a gas. Alternatively, the metallic cross-linker could be applied as a solid.

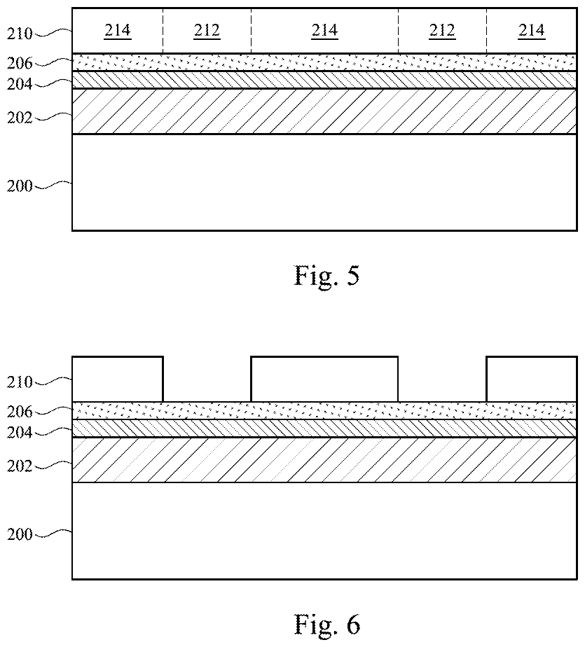

Continuing, in step 115 of FIG. 1A, the photoresist layer 210 is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. In other embodiments, electron-beam (e-beam) radiation is used. Electron beams can be characterized by the energy of the beam, which in some embodiments ranges from about 5 volts (V) to about 200 kilovolts (kV). This step results in some portions of the photoresist layer being exposed to radiation, and some portions of the photoresist not being exposed to radiation. This exposure causes some portions of the photoresist to remain soluble in the developer and other portions of the photoresist to become insoluble in the developer. Referring now to FIG. 5, the photoresist layer 210 now includes soluble regions 212 and insoluble regions 214. It is noted for reference that EUV and e-beam radiation exposure typically occur under vacuum.

Prior to radiation exposure, the metallic cross-linker does not react with the metallic photoresist. When exposed to radiation, the ligands of the metallic cross-linker are cleaved from the metal core. The metal core remains stable, because the radiation energy is not sufficient to break the bonds within the metal core. In addition, without being bound by theory, the covalent bonds within the metallic cross-linker will not be cleaved through subsequent heat treatment steps. As a result, a number of reaction sites may be generated upon the metal core. The metal core may then cross-link with other metal cores, as well as the metallic photoresist. The ligands may cross-link with each other as well, or may not react at all.

Optionally, in step 120 of FIG. 1A, a post exposure bake (PEB) occurs after the exposure to radiation. The PEB step can be used to complete any cross-linking within the photoresist. In addition, the PEB step may reduce mechanical stress that might build up during the prior steps. In some particular embodiments, the PEB occurs at a temperature of about 40° C. to about 250° C., including from about 100° C. to about 250° C. or from about 90° C. to about 150° C. The time for the PEB may range from about 10 seconds to about 10 minutes, and may vary depending on the thickness of the photoresist layer.

Next, in step 125 of FIG. 1A, the photoresist layer 210 is developed using a developer. The developer may be applied by spin coating, spraying, or other suitable process. The soluble portions of the photoresist layer are dissolved and washed away during the development step, leaving behind a patterned photoresist layer. This may be done, for example, by spin drying. Suitable developers may include PGMEA, PGME, PGEE, GBL, cyclohexanone, ethyl lactate, methanol, ethanol, propanol, n-butanol, acetone, DMF, isopropyl alcohol (IPA), THF, MIBC, n-butyl acetate, MAK, or isobutyl propionate, i.e. the same solvent used in the photoresist solution. Other developers could include aqueous tetramethylammonium hydroxide (TMAH), isoamyl acetate, cyclohexanone, 5-methyl-2-hexanone, methyl-2-hydroxyisobutyrate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. The resulting structure is illustrated in FIG. 6. As seen here, the soluble regions have been washed away, resulting in a patterned photoresist layer.

In optional step 130 of FIG. 1A, a post develop bake or “hardbake” may be performed after development. This can be done to stabilize the photoresist pattern after development, for optimum performance in subsequent steps. In some particular embodiments, the hardbake occurs at a temperature of about 100° C. to about 160° C. The time for the hardbake may range from about 1 minute to about 10 minutes, and may vary depending on the thickness of the photoresist layer.

The various baking steps may be useful in enhancing the reaction of the metallic cross-linker with the metallic photoresist. In some embodiments, a baking step may occur at any temperature ranging from about 40° C. to about 300° C.

Continuing, then, portions of the upper underlayer 206, the lower underlayer 204, and the first material layer 202 are exposed below the first patterned photoresist layer are now exposed.

In optional step 134 of FIG. 1A, the underlayer(s) 206, 204 are etched, thus transferring the photoresist pattern to the underlayers. Then, in step 140 of FIG. 1A, the first material layer 202 is etched, thus transferring the photoresist pattern to the first material layer. Desirably, each of the etchants for these layers differs significantly from that of the other layers, which improves the LWR in the first material layer.

Generally, these etching steps may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Referring now to FIG. 1B, the two different treatment options are shown more clearly here. In the photoresist coating step 105 and the developing step 125, the metallic cross-linker can be directly mixed into the photoresist solution or the development solution. This is indicated in dotted lines. Alternatively, the metallic cross-linker can be used in the form of a treatment solution which is applied to the photoresist. More desirably, the metallic cross-linker is used before, during, or after a step in which energy is added to the photoresist. Those include the radiation exposure step 115, the pre-bake step 110, and the post exposure bake step 120, in which light energy or thermal energy are added. This is indicated with solid lines.

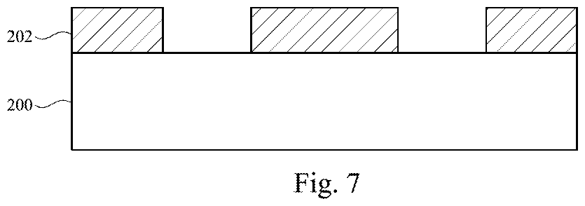

Next, in step 145 of FIG. 1A, the patterned photoresist layer 210 is removed. In optional step 146, the upper underlayer 206 is removed. In optional step 148, the lower underlayer 204 is removed. The photoresist layer, the upper underlayer, and the lower underlayer can be removed using conventional means such as plasma stripping, solvent, or chemical-mechanical planarization (CMP). The resulting structure is illustrated in FIG. 7, with the first material layer 202 being patterned.

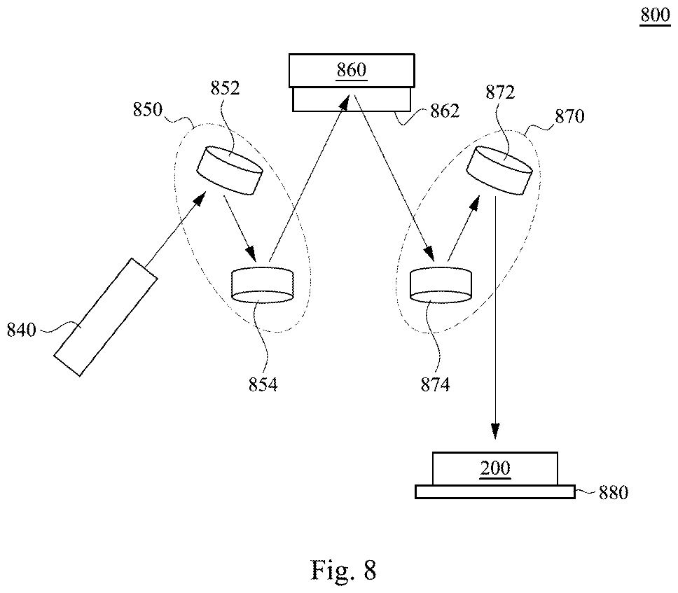

FIG. 8 is an illustrative schematic diagram, not drawn to scale, illustrating the various components of an extreme ultraviolet (EUV) photolithography system which generates the radiation to which the photoresist is exposed. Generally, the EUV photolithography system 800 begins with an EUV light source 840 that generates EUV light or radiation. Downstream of the EUV light source is an illumination stage 850 in which the EUV light may be collected and focused as a beam, for example using field facet mirror 852 that splits the beam into a plurality of light channels. These light channels can then directed using one or more relay mirrors 854 onto the plane of the photomask. The photomask 860 may include a pellicle membrane 862, through which the radiation passes before and/or after contacting the photomask. Downstream of the photomask 860 is the projection optics module 870, which is configured for imaging the pattern of the photomask onto the semiconductor wafer substrate 200. The projection optics module 870 may include refractive optics or reflective optics for carrying the image of the pattern defined by the photomask. Illustrative mirrors 872, 874 are shown. The wafer substrate 200 is positioned upon a wafer stage 880, which can move for imaging. The lithography system can include other modules or be integrated with or coupled to other modules.

Additional processing steps may be performed to fabricate a semiconductor device or integrated circuit. Examples of such steps may include ion implantation, deposition of other materials, etching, etc.

Use of the metallic cross-linker with the specified ligands provides some advantages. The hardness of the metallic photoresist layer can be increased by 1% or more. In some particular embodiments, the resulting hardness of the metallic photoresist layer is from about 0.01 GPa to about 100 GPa, although other ranges and values are within the scope of this disclosure. The line width roughness (LWR) and critical dimension uniformity (CDU) can be improved by 3% or more. The optimum energy (Eop) for lithography can also be improved by 3% or more. The metallic photoresist may have improved thermal stability as well, which also improves pattern fidelity. Processes with a pitch of 40 nanometers or lower can be improved using these components in the photoresist.

Some embodiments of the present disclosure thus relate to methods for preparing a patterned photoresist layer. A substrate is coated with a photoresist solution that includes a metallic cross-linker. The metallic cross-linker comprises a metal core and a plurality of ligands. The plurality of ligands comprises: at least one ligand that comprises at least one vinyl group or at least one acetylene group; or at least one ligand that comprises an acrylate; or at least one ligand that comprises a cinnamate; or at least one ligand that cannot participate in a crosslinking reaction.

Other embodiments of the present disclosure relate to a photoresist solution that comprises a metallic photoresist and a metallic cross-linker. The metallic cross-linker comprises a metal core and a plurality of ligands. The plurality of ligands comprises: at least one ligand that comprises at least one vinyl group or at least one acetylene group; or at least one ligand that comprises an acrylate; or at least one ligand that comprises a cinnamate; or at least one ligand that cannot participate in a crosslinking reaction.

Finally, other embodiments of the present disclosure relate to methods that use a photoresist solution. The substrate is coated with a photoresist solution. The coated substrate is pre-baked to cure the photoresist solution and form a photoresist layer. The photoresist layer is then exposed to radiation to pattern the photoresist layer. An optional post-exposure bake of the coated substrate may be performed. The patterned photoresist layer is then developed using a developer. The photoresist solution may include a metallic cross-linker. Alternatively, the coated substrate is treated with a treatment solution that contains a metallic cross-linker during or after any of the process steps prior to radiation exposure. The metallic cross-linker comprises a metal core and a plurality of ligands. The plurality of ligands comprises: at least one ligand that comprises at least one vinyl group or at least one acetylene group; or at least one ligand that comprises an acrylate; or at least one ligand that comprises a cinnamate; or at least one ligand that cannot participate in a crosslinking reaction.

Additional embodiments of the present disclosure relate to a metallic cross-linker which can be used with a metallic photoresist. The metallic cross-linker comprises a metal core and a plurality of ligands. The plurality of ligands comprises: at least one ligand that comprises at least one vinyl group or at least one acetylene group; or at least one ligand that comprises an acrylate; or at least one ligand that comprises a cinnamate; or at least one ligand that cannot participate in a crosslinking reaction.

Further embodiments of the present disclosure relate to a metallic photoresist layer with enhanced hardness. The metallic photoresist layer is further hardened by application of a metallic cross-linker (as described above) and subsequent radiation exposure. This causes bonding between the metallic photoresist layer and the metallic cross-linker.

Also disclosed herein in some embodiments are wafer substrates with a hardened metallic photoresist layer thereon. The hardened metallic photoresist layer is produced as described above.

Also disclosed herein are photolithography systems having a wafer substrate therein with a hardened metallic photoresist layer thereon. The photolithography system includes an EUV light source, an illumination stage, a photomask, a projection optics module, and a wafer stage upon which the wafer substrate rests.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for preparing a patterned photoresist layer, comprising:
coating a substrate with a photoresist solution that includes a metallic cross-linker;
wherein the metallic cross-linker comprises a metal core and a plurality of ligands, wherein the metal core has 1 to 12 metal atoms, and the plurality of ligands comprises:
at least one ligand that comprises at least one vinyl group or at least one acetylene group; or
at least one ligand that comprises an acrylate; or
at least one ligand that comprises a cinnamate; or
at least one ligand that cannot participate in a crosslinking reaction.

2. The method of claim 1, wherein the at least one ligand that comprises at least one vinyl group or at least one acetylene group is an alkene or an alkyne.

3. The method of claim 1, wherein the at least one ligand that comprises at least one vinyl group or at least one acetylene group also contains at least one aromatic group.

4. The method of claim 1, wherein the at least one ligand that comprises at least one vinyl group or at least one acetylene group has the structure of Formula (1): 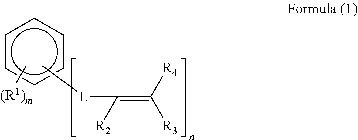
where R₁, R₂, R₃, and R₄, are independently hydrogen or hydrocarbon; L is alkyl or is a single bond; n is an integer from 1 to 5; and m+n is an integer from 1 to 5.

5. The method of claim 1, wherein the at least one ligand that comprises an acrylate has the structure of Formula (2): 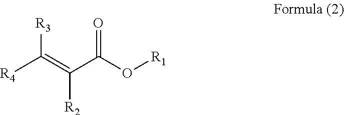
where R₁, R₂, R₃, and R₄ are independently hydrogen, hydrocarbon, or substituted hydrocarbon.

6. The method of claim 1, wherein the at least one ligand that comprises a cinnamate has the structure of Formula (3): 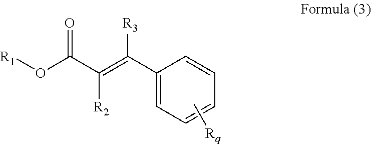
where R, R₁, R₂, and R₃ are independently hydrogen, hydrocarbon, or substituted hydrocarbon; and q is an integer from 0 to 5.

7. The method of claim 1, wherein the at least one ligand that cannot participate in a crosslinking reaction is a primary alkane.

8. The method of claim 1, wherein each ligand has a molecular weight of about 30 to about 2000.

9. The method of claim 1, wherein each ligand has from 1 to 20 carbon atoms.

10. The method of claim 1, wherein the plurality of ligands comprises two different ligands, or comprises three different ligands, or comprises four different ligands.

11. The method of claim 1, wherein the ligands in the plurality of ligands all have the same structure.

12. The method of claim 1, wherein each ligand includes at least one substituent which is halogen, —OH, —SH, —NO₂, —SO₂R, —SO₃R, —CN, —COR, —CO₂R, or —CONR₂, wherein each R is independently hydrogen or alkyl.

13. The method of claim 1, wherein the metal core comprises Ag, Cd, In, Sn, Sb, Te, Cs, Au, Hg, Ti, Pb, Bi, Po, At, or Ba.

14. The method of claim 1, further comprising:
pre-baking the applied photoresist solution to form a photoresist layer;
exposing the photoresist layer to radiation to pattern the photoresist layer; and
developing the photoresist layer to obtain a patterned photoresist layer.

15. A photoresist solution, comprising:
a metallic photoresist and a metallic cross-linker;
wherein the metallic cross-linker comprises a metal core and a plurality of ligands, wherein the metal core has 1 to 12 metal atoms, and the plurality of ligands comprises:
at least one ligand that comprises at least one vinyl group or at least one acetylene group; or
at least one ligand that comprises an acrylate; or
at least one ligand that comprises a cinnamate; or
at least one ligand that cannot participate in a crosslinking reaction.

16. The photoresist solution of claim 15, wherein the plurality of ligands comprises two different ligands, or comprises three different ligands, or comprises four different ligands.

17. The photoresist solution of claim 15, wherein the ligands in the plurality of ligands all have the same structure.

18. A method, comprising:
coating a substrate with a photoresist solution;
pre-baking the coated substrate to cure the photoresist solution and form a photoresist layer;
exposing the photoresist layer to radiation to pattern the photoresist layer;
optionally performing a post-exposure bake of the coated substrate; and
developing the patterned photoresist layer using a developer;
wherein the photoresist solution includes a metallic cross-linker; or
wherein the coated substrate is treated with a treatment solution that contains a metallic cross-linker during or after the coating step or the pre-baking step; and
wherein the metallic cross-linker comprises a metal core and a plurality of ligands, wherein the metal core has 1 to 12 metal atoms, and the plurality of ligands comprises:
at least one ligand that comprises at least one vinyl group or at least one acetylene group; or
at least one ligand that comprises an acrylate; or
at least one ligand that comprises a cinnamate; or
at least one ligand that cannot participate in a crosslinking reaction.

19. The method of claim 18, wherein the treatment with the treatment solution containing the metallic cross-linker is performed by vaporizing the treatment solution.

20. The method of claim 18, wherein the metallic cross-linker is used in an amount of about 0.001 at % to about 50 at % relative to a metallic photoresist in the photoresist solution.
